(19) United States
(12) Patent Application Publication
(10) Pub. No.: US 2021/0296579 A1
(43) Pub. Date: Sep. 23, 2021

(54) RESISTIVE RANDOM ACCESS MEMORY AND METHOD FOR PREPARING THE SAME

(71) Applicant: Institute of Microelectronics, Chinese Academy of Sciences, Beijing (CN)

(72) Inventors: Qi Liu, Beijing (CN); Hangbing Lv, Beijing (CN); Ming Liu, Beijing (CN); Xiaoxin Xu, Beijing (CN); Cheng Lu, Beijing (CN); Shengjie Zhao, Beijing (CN)

(21) Appl. No.: 17/250,553

(22) PCT Filed: Aug. 2, 2018
(86) PCT No.: PCT/CN2018/098315

§ 371 Date: Feb. 2, 2021

(51) Int. Cl. H01L 45/00

(52) U.S. Cl. CPC H01L 45/10; H01L 45/1233; H01L 45/1253; H01L 45/1641; H01L 45/1616; H01L 45/1625; H01L 45/146

(57) ABSTRACT

The present disclosure discloses a resistive random access memory, and the resistive random access memory includes a lower electrode layer, a ferroelectric material layer, and an upper electrode layer arranged in sequence from bottom to top, wherein the ferroelectric material layer includes a doped HfO₂ ferroelectric thin film.

### TECHNICAL FIELD

The embodiments of the present disclosure relates to a field of microelectronic manufacturing and memory technology, and in particular to a resistive random access memory and a method for preparing the same.

### BACKGROUND

Ferroelectric materials have a wide range of applications in the field of microelectronic manufacturing and memory technology. In the related art, the ferroelectric materials are mostly used in ferroelectric memory. In traditional integrated architectures of the ferroelectric memory, a transistor and a ferroelectric capacitor need to be integrated, and this 1T1C structure is not conducive to large-scale integration and is destructive reading. In addition, traditional ferroelectric materials are not compatible with CMOS processes. For example, an application of a ferroelectric thin film with a perovskite structure to a silicon-based ferroelectric device may lead to following problems: a ferroelectric size effect, a small band gap, a mismatch with silicon interface, and a degradation of properties due to heat treatment during crystallization. In addition, a memory based on ferroelectric materials generally has a relatively large thickness, resulting in a low current density, which limits developments of device performances and miniaturization.

Therefore, it is necessary to study a memory based on ferroelectric materials with improved structure and performance.

### SUMMARY

The embodiments of the present disclosure aim to provide a resistive random access memory based on ferroelectric materials and a method for preparing the same.

According to an aspect of the present disclosure, a resistive random access memory is provided, where the resistive random access memory includes a lower electrode layer, a ferroelectric material layer, and an upper electrode layer arranged in sequence from bottom to top, where the ferroelectric material layer includes a doped HfO₂ ferroelectric thin film.

According to some embodiments, the ferroelectric material layer includes a HfO₂ ferroelectric thin film doped with at least one element of Zr, Al, Si, and La.

According to some embodiments, a mole percentage of a doping element is 0.1 to 50 mol %.

According to some embodiments, the lower electrode layer includes one or more of elementary substances W, Al, Ti, Ta, Ni, and Hf, and conductive metal compounds TiN and TaN.

According to some embodiments, the upper electrode layer includes one or more of elementary substances W, Al, Cu, Ru, Ti, and Ta, and one or more of conductive metal compounds TiN, TaN, IrO₂, ITO, and IZO.

According to another aspect of the present disclosure, a method for preparing a resistive random access memory is provided, including: forming a lower electrode layer on the substrate; forming a ferroelectric material layer on the lower electrode layer, where the ferroelectric material layer comprises a doped HfO₂ ferroelectric thin film; and forming an upper electrode layer on the ferroelectric material layer.

According to some embodiments, the ferroelectric material layer includes a HfO₂ ferroelectric thin film doped with at least one element of Zr, Al, Si, and La.

According to some embodiments, a doping method includes an atomic layer deposition (ALD) method or a co-sputtered method.

According to some embodiments, after the ferroelectric material layer is formed on the lower electrode layer, an annealing treatment is performed, an annealing temperature is 400 to 1000° C., and an annealing time is 30 to 300 s.

In the resistive random access memory according to the embodiments of the present disclosure, by applying the doped HfO₂ ferroelectric thin film to a structure of a metal-insulating layer-metal (MIM) resistive memory, a memory having both characteristics of high speed and high endurance of the ferroelectric memory and a characteristic of easy integration of the resistive random access memory may be obtained. As the doped HfO₂ ferroelectric thin film has a polycrystalline structure, it may be better compatible with a substrate, ensuring a stability of a device structure. The resistive random access memory of the present disclosure does not require additional transistors, which may greatly reduce an area of a device, and may be more conducive to three-dimensional integration. Moreover, non-destructive reading is used, no additional write-back operation is required, and the reading efficiency is improved. In addition, the HfO₂ ferroelectric thin film may still maintain good ferroelectric properties at a small thickness, which may greatly increase a current density and further improve a scalability of the memory.

### BRIEF DESCRIPTION OF THE DRAWINGS

Through following description of the present disclosure with reference to the accompanying drawings, other purposes and advantages of the present disclosure will be apparent and may help a comprehensive understanding of the present disclosure.

FIG. 1 shows a schematic structural diagram of a resistive random access memory according to an exemplary embodiment of the present disclosure.

FIG. 2 shows a flowchart of a method for preparing the resistive random access memory of FIG. 1.

FIG. 3 shows a current-voltage characteristic curve diagram of the resistive random access memory of FIG. 1 in a DC scan mode.

### DETAILED DESCRIPTION OF EMBODIMENTS

In order to make the objectives, technical solutions, and advantages of the present disclosure clearer, the following further describes the present disclosure in detail with reference to specific embodiments and drawings. It should be noted that, in the drawings or description of the specification, similar or identical parts use the same drawing numbers. The implementations not shown or described in the drawings are those known to those of ordinary skill in the art. In addition, although the present disclosure may provide an example of a parameter containing a specific value, it should be understood that the parameter does not need to be exactly equal to the corresponding value, but may be approximated to the corresponding value within an acceptable error tolerance or design constraint. The directional terms mentioned in the embodiments, such as “upper”, “lower”, “front”, “rear”, “left”, “right”, etc., are only directions with reference to the drawings. Therefore, the directional terms used are used to illustrate and not to limit the protection scope of the present disclosure.

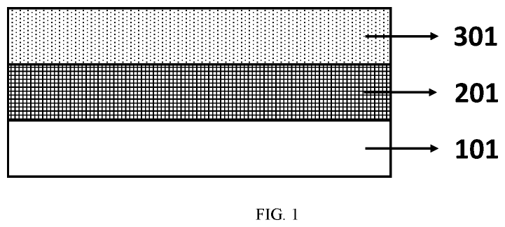

FIG. 1 shows a schematic structural diagram of a resistive random access memory according to an exemplary embodiment of the present disclosure. As shown in FIG. 1, the resistive random access memory includes a lower electrode layer 101, a ferroelectric material layer 201, and an upper electrode layer 301 arranged in sequence from bottom to top, where the ferroelectric material layer 201 includes a doped HfO₂ ferroelectric thin film. In the resistive random access memory according to the embodiment of the present disclosure, by applying the doped HfO₂ ferroelectric thin film to a structure of a metal-insulating layer-metal (MIM) resistive memory, a memory having characteristics of high speed and high endurance of the ferroelectric memory and a characteristic of easy integration of the resistive random access memory may be obtained. As the doped HfO₂ ferroelectric thin film has a polycrystalline structure, it may be better compatible with a substrate, ensuring a stability of a device structure. The resistive random access memory of the present disclosure does not require additional transistors, which may greatly reduce an area of a device, and may be more conducive to three-dimensional integration. Moreover, non-destructive reading is used, no additional write-back operation is required, and the reading efficiency is improved. In addition, the HfO₂ ferroelectric thin film may still maintain good ferroelectric properties at a small thickness, which may greatly increase a current density and further improve a scalability of the memory.

The lower electrode layer 101 may include one or more of elementary substances W, Al, Ti, Ta, Ni, Hf, and conductive metal compounds TiN and TaN, and may be prepared by one of an electron beam evaporation, a chemical vapor deposition, a pulsed laser deposition, an atomic layer deposition, and a sputtering method. In an embodiment of the present disclosure, a thickness and a shape of the lower electrode layer 101 are not limited.

The upper electrode layer 301 may include one or more of elementary substances W, Al, Cu, Ru, Ti, Ta, and conductive metal compounds TiN, TaN, IrO₂, ITO, IZO, and may be prepared by one of an electron beam evaporation, a chemical vapor deposition, a pulsed laser deposition, an atomic layer deposition, and a sputtering method. In an embodiment of the present disclosure, a thickness and a shape of the upper electrode layer 301 are not limited.

The ferroelectric material layer 201 formed between the lower electrode layer 101 and the upper electrode layer 301 may specifically include a HfO₂ ferroelectric thin film doped with at least one element of Zr, Al, Si, and La. The binary oxide HfO₂ has a high dielectric constant, a wide band gap, and a good compatibility with CMOS processes. The HfO₂ thin film has a good ferroelectricity after being doped, and forms a metal-insulating layer-metal (MIM) structure with the lower electrode layer 101 and the upper electrode layer 301. This kind of structure based on ferroelectric material has a characteristic of a diode with adjustable direction. The diode current is modulated by an electric domain flipping (ferroelectric diode phenomenon for short) to realize a function of the resistive random access memory, and due to a mechanism of ferroelectric flipping, a theoretical speed may reach ns level and may be used for memory applications. Furthermore, compared with traditional ferroelectric thin films, the polycrystalline structure of the doped HfO₂ ferroelectric thin film reduces requirements on the substrate. In addition, by virtue of a mature technology combined with silicon base, the reliability and stability of the device may also be guaranteed. In addition, the HfO₂ ferroelectric thin film may still maintain good ferroelectric properties even when a thickness of the HfO₂ ferroelectric thin film is small (10 nm). In comparison, a thickness of a traditional ferroelectric material is generally about 200 nm. As a result, the resistive random access memory of the present disclosure may greatly reduce a thickness of a device, which is conducive to a miniaturization of the memory. In addition, the thickness of the traditional ferroelectric material limits a current density of the memory, which may generally only be maintained at about 20 mA/cm². However, in order for the amplifier in a memory readout circuit to effectively read the current, the current density of the device needs to be as high as possible. The resistive random access memory of the present disclosure may maintain the current density at a relatively high level (200 A/cm²), making the reading of the memory readout circuit more accurate.

In an embodiment of the present disclosure, a mole percentage of doping elements in the HfO₂ ferroelectric thin film may be 0.1 to 50 mol %, and a doping method may include an atomic layer deposition (ALD) method or a co-sputtered method.

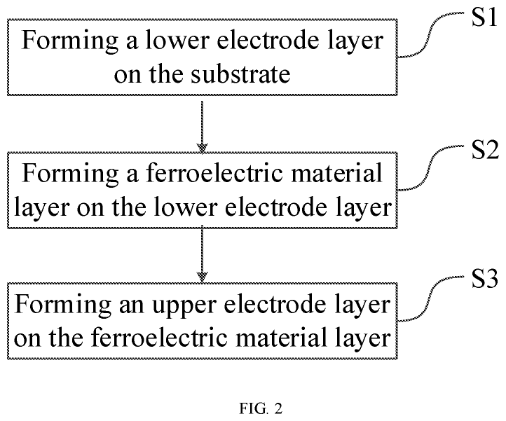

FIG. 2 shows a flowchart of a method for preparing the resistive random access memory of FIG. 1. As shown in FIG. 2, the method for preparing the resistive random access memory may include the following steps:

S1, forming a lower electrode layer 101 on a substrate;

S2, forming a ferroelectric material layer 201 on the lower electrode layer 101, where the ferroelectric material layer 201 may include a doped HfO₂ ferroelectric thin film, specifically, the ferroelectric material layer 201 may include a HfO₂ ferroelectric thin film doped with at least one element of Zr, Al, Si, and La;

S3, forming an upper electrode layer 301 on the ferroelectric material layer 201.

Further, after the ferroelectric material layer 201 is formed on the lower electrode layer 101, an annealing treatment is performed, an annealing temperature is in 400 to 1000° C., and an annealing time is in 30 to 300 s.

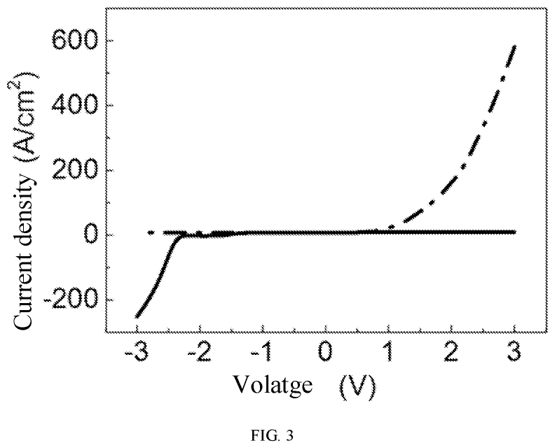

FIG. 3 shows a current-voltage characteristic curve of the resistive random access memory of FIG. 1 in a DC scan mode, where a dotted line represents a curve after scanning with a scan voltage of 6V, and a solid line represents a curve after scanning with a scan voltage of −6V. As shown in FIG. 6, when the scan voltage is applied from 0 to 6V, the device exhibits a forward turn-on diode characteristic; when the bias scan voltage is applied from 0 to −6V, the device exhibits a reverse turn-on diode characteristic. Under a reading voltage of 2V, the current density may reach 200 A/cm².

The description is given below based on specific embodiments.

### Embodiment 1

A resistive random access memory based on the Hf_{0.5}Zr_{0.5}O₂ ferroelectric layer is prepared, and a process for preparing the same is as follows.

Step 1: a sputtering method is used to form a TiN lower electrode layer, and process conditions are: a power of 25 W to 500 W; a pressure of 0.1 Pa to 100 Pa; an Ar gas flow rate of 0.5 sccm to 100 sccm; and a thickness of the prepared TiN lower electrode layer is 10 nm to 500 nm.

Step 2: ALD is used to cyclically grow HfO₂ and ZrO₂ on the TiN lower electrode layer to obtain the Hf_{0.5}Zr_{0.5}O₂ ferroelectric layer, and process conditions are: a power of 25 W to 500 W; a pressure of 0.1 Pa to 100 Pa; a gas flow rate of 60 sccm; a temperature of 250° C. to 300° C.; a rate of about 0.07 nm/cycle; and after a cycle of HfO₂ is grown, a cycle of ZrO₂ is grown immediately, the two circles are repeated in this way, so that the two materials are mixed and deposited at a molar ratio of 1:1.

Step 3: an annealing treatment is performed, an annealing temperature is 400° C., and an annealing time is 30 s.

Step 4: a sputtering method is used to form a TiN upper electrode layer on the Hf_{0.5}Zr_{0.5}O₂ ferroelectric layer, and process conditions are: a power of 25 W to 500 W; a pressure of 0.1 Pa to 100 Pa; an Ar gas flow rate of 0.5 sccm to 100 sccm; and a thickness of the prepared TiN upper electrode layer is 10 nm to 500 nm.

Thus, the resistive random access memory of Embodiment 1 is completed.

Although the present disclosure has been described with reference to the accompanying drawings, the embodiments disclosed in the accompanying drawings are intended to exemplify the implementation of the present disclosure and should not be understood as a limitation of the present disclosure.

Those of ordinary skill in the art will understand that changes may be made to these embodiments without departing from the principle and spirit of the general idea of the present disclosure, and the scope of the present disclosure is defined by the claims and their equivalents.

What is claimed is:

1. A resistive random access memory, comprising,
a lower electrode layer, a ferroelectric material layer, and an upper electrode layer arranged in sequence from bottom to top, wherein the ferroelectric material layer comprises a doped HfO₂ ferroelectric thin film.

2. The resistive random access memory according to claim 1, wherein the ferroelectric material layer comprises a HfO₂ ferroelectric thin film doped with at least one element of Zr, Al, Si, and La.

3. The resistive random access memory according to claim 2, wherein a mole percentage of a doping element is 0.1 to 50 mol %.

4. The resistive random access memory according to claim 1, wherein the lower electrode layer comprises one or more of elementary substances W, Al, Ti, Ta, Ni, and Hf, and conductive metal compounds TiN and TaN.

5. The resistive random access memory according to claim 1, wherein the upper electrode layer comprises one or more of elementary substances W, Al, Cu, Ru, Ti, and Ta, and conductive metal compounds TiN, TaN, IrO₂, ITO, and IZO.

6. A method for preparing a resistive random access memory, comprising:
forming a lower electrode layer on the substrate;
forming a ferroelectric material layer on the lower electrode layer, wherein the ferroelectric material layer comprises a doped HfO₂ ferroelectric thin film; and
forming an upper electrode layer on the ferroelectric material layer.

7. The method according to claim 6, wherein the ferroelectric material layer comprises a HfO₂ ferroelectric thin film doped with at least one element of Zr, Al, Si, and La.

8. The method according to claim 6, wherein a doping method comprises an atomic layer deposition (ALD) method or a co-sputtered method.

9. The method according to claim 6, wherein after the ferroelectric material layer is formed on the lower electrode layer, an annealing treatment is performed, an annealing temperature is 400 to 1000° C., and an annealing time is 30 to 300 s.
